(19) United States
(12) Patent Application Publication
(10) Pub. No.: US 2026/0051718 A1
(43) Pub. Date: Feb. 19, 2026

(54) VCSEL device having ring-shaped Zn-diffusion defined light-emission aperture

(71) Applicant: Jin-Wei Shi, Taoyuan City (TW)

(72) Inventor: Jin-Wei Shi, Taoyuan City (TW)

(21) Appl. No.: 19/184,570

(22) Filed: Apr. 21, 2025

Related U.S. Application Data
(60) Provisional application No. 63/683,765, filed on Aug. 16, 2024.

(51) Int. Cl. H01S 5/183

(52) U.S. Cl. CPC H01S 5/18394; H01S 5/18308

(57) ABSTRACT

Provided is a VCSEL device having a ring-shaped Zn-diffusion defined light-emission aperture and having single-mode or multi-mode output power and strong immunity against optical feedback, playing an important role in further enhancing a packaging density in a CPO system. A VCSEL cavity structure having therein a ring-shaped Zn-diffusion defined light-emission aperture is optimized to enhance the output power and speed of an 850 nm VCSEL in a single-mode fiber (SMF), achieving a record-high 16 mW SM output power and a 3-dB E-O bandwidth of 18 GHz. The replacement of a Zn-diffusion structure with the ring-shaped light-emission aperture allows light emission to be focused into the light-emission ring defined by the ring-shaped light-emission aperture to achieve, for example, wide E-O bandwidth (27 GHz), high SM power (6.7 mW), low-RIN (−137 dB/Hz) and invariant 56 Gbps eye patterns under a strong optical feedback (−6 dB), and thus achieve high-speed operations.

### FIELD OF THE INVENTION

The present invention relates to a VCSEL device having a ring-shaped Zn-diffusion defined light-emission aperture. More particularly, the present invention relates to replacing an aperture of a Zn-diffusion structure with a ring-shaped light-emission aperture. Much more particularly, the present invention relates to focusing light emission into a light-emission ring defined by the Zn-diffusion structure such that the light-emission ring is near the edge of a current-confined region to not only effectively shorten a hole drift distance from a p-contact to the light-emission aperture but also further enhance injection efficiency and slope efficiency and minimize the spatial hole burning effect.

### DESCRIPTION OF THE PRIOR ART

The boom in the development of artificial intelligence (AI) technology and the rapid increase of the clock rate in the modern GPU and CPU have driven the data rate over 200 Gbit/sec per lane in modern optical interconnect (OI) and data communication systems. Co-Packaged Optics (CPO) has become an effective solution to achieve the afore-mentioned data rate because of the elimination of the large propagation loss of electrical signal in printed circuit boards. Alternatives to CPO rely on the silicon photonics (SiP) technology with single-mode fiber (SMF) channels. The VCSEL based design exhibits a much lower energy per bit due to the higher modulation efficiency of the light source and the elimination of significant input/output coupling loss between the waveguide and the SMF. Nevertheless, in VCSEL platforms with multi-mode fiber (MMF) embedded inside, the pitch-size of the channels is usually much larger than that of SiP ones due to the significant difference in core diameter between MMF and SMF. To further improve the package density in the VCSEL-based CPO it becomes essential to downscale both the core diameter and pitch size of the channel. This drives the development of high-speed and SM VCSELs, which produce far-field patterns with a much narrower divergence angle than that of the MM ones. It allows more efficient coupling of the VCSEL output light into the SMF with small core diameters.

Recently, high-performance transmission has been demonstrated through the use of a high-speed 1060 nm SM VCSEL array and multi-core fiber (MCF) via a densely package on a CPO platform.

The most straightforward way to obtain a (quasi-) SM output in high-speed VCSELs is to downscale the size of the oxide apertures to less than about 4 μm to suppress the higher-order transverse modes. However, sustaining good reliability with this kind of SM VCSEL remains a challenge because of the high current density required during high-speed operation. In addition, the restricted maximum output power (usually around 2 mW) from such small aperture VCSELs limits the power budget in the SMF based CPO, where the significant coupling loss between the VCSEL and the SMF remains a challenge. One approach for increasing the current-confined aperture size and maximize the SM output power is to insert an additional optical aperture, using Zn-diffusion or surface relief. However, the high photon density in the peak of the Gaussian-like far-field pattern of the SM VCSEL's output usually results in a serious spatial hole burning (SHB) effect. This is often accompanied by an unwanted low-frequency roll-off in the E-O frequency response and more noticeable resonance in the relative intensity noise (RIN) spectrum, which seriously degrades the quality of the eye patterns for large-signal transmission. In addition, the other important challenge for the practical application of SM VCSELs is that their performance is more sensitive to parasitic optical reflection induced by device packaging than that of their MM counterparts.

Therefore, the prior art cannot meet user needs.

### BRIEF SUMMARY OF THE INVENTION

Therefore, the main purpose of the present invention is to overcome the aforementioned drawbacks of prior art and provide a VCSEL device having a ring-shaped Zn-diffusion defined light-emission aperture to replace an aperture of a Zn-diffusion structure with a ring-shaped light-emission aperture and focus light emission into a light-emission ring defined by the ring-shaped light-emission aperture so as to achieve excellent VCSEL device performance, such as achieving wide E-O bandwidth (27 GHz), high SM power (6.7 mW), low-RIN (−137 dB/Hz), and invariant 56 Gbps eye patterns under a strong optical feedback (−6 dB), and thereby enable high-speed operations.

To achieve the above purposes, the present invention is a VCSEL device having a ring-shaped Zn-diffusion defined light-emission aperture, comprising: a top DBR disposed in an epitaxial structure of the VCSEL device and having therein a Zn-diffusion structure, with the Zn-diffusion structure located at a ring-shaped light-emission aperture in a central region on a top surface of the top DBR to focus light emission into a light-emission ring defined by the Zn-diffusion structure, allowing the light-emission ring to be near an edge of a current-confined region disposed in the epitaxial structure, so as to effectively shorten a hole drift distance from a p-contact to the light-emission aperture, further enhance injection efficiency and slope efficiency, and minimize a spatial hole burning effect.

In the embodiment of the present invention, the epitaxial structure is stacked on a substrate selected from one of P-type, N-type, and semi-insulating semiconductor.

In the embodiment of the present invention, the epitaxial structure further comprises a bottom DBR and a light-emission region (active region) stacked on the bottom DBR, with the top DBR being stacked on the light-emission region, allowing one of a wet oxidation, etching-defined undercut structure, and ion-implantation region to be defined on the light-emission region, with the current-confined region being a central portion of one of the undercut structure and the ion-implantation region.

In the embodiment of the present invention, the diameter of the current-confined region closely approximates the outer diameter of the light-emission ring defined by the Zn-diffusion structure and is less than 10 μm.

In the embodiment of the present invention, the VCSEL device is one of a single-mode (SM) VCSEL and a multi-mode (MM) VCSEL.

In the embodiment of the present invention, the VCSEL device is an 850 nm SM VCSEL effective in enhancing the output power and speed of the VCSEL in a single-mode fiber (SMF).

In the embodiment of the present invention, the VCSEL device achieves excellent VCSEL performance by achieving wide E-O bandwidth (27 GHz), high SM power (6.7 mW), low-RIN (−137 dB/Hz), and invariant 56 Gbps eye patterns under a strong optical feedback (−6 dB) so as to achieve high-speed operations.

In the embodiment of the present invention, the VCSEL device enhances the immunity against optical feedback to achieve an SM output power of 16 mW and a 3-dB E-O bandwidth of 18 GHz.

### BRIEF DESCRIPTION OF THE DRAWINGS

FIG. 1A is a cross-sectional view of device A having a ring-shaped Zn-diffusion defined light-emission aperture according to the present invention.

FIG. 1B (PRIOR ART) is a cross-sectional view of device B exemplarily having a conventional Zn-diffusion structure.

FIG. 1C (PRIOR ART) is a cross-sectional view of reference device C exemplarily having not undergone any Zn-diffusion process.

FIG. 1D is a top view of a VCSEL device having a ring-shaped Zn-diffusion defined light-emission aperture according to the present invention.

FIG. 2A is a graph showing the L-I curve of device A measured according to present invention.

FIG. 2B (PRIOR ART) is a graph showing the L-I curve of device B.

FIG. 2C (PRIOR ART) is a graph showing the L-I curve of device C.

FIG. 3A is a bias voltage spectral diagram of device A according to the present invention.

FIG. 3B is a bias voltage spectral diagram of device B according to the present invention.

FIG. 3C is a bias voltage spectral diagram of device C according to the present invention.

FIG. 4A is a graph illustrative of measured bias-dependent E-O frequency responses of device A according to the present invention.

FIG. 4B is a graph illustrative of measured bias-dependent E-O frequency responses of device B according to the present invention.

FIG. 4C is a graph illustrative of measured bias-dependent E-O frequency responses of device C according to the present invention.

FIG. 5A shows an image of BTB eye patterns of device A, measured without reflection, according to the present invention.

FIG. 5B shows an image of BTB eye patterns of device A, measured under an optical feedback (−12 dB), according to the present invention.

FIG. 5C shows an image of BTB eye patterns of device A, measured under an optical feedback (−6 dB), according to the present invention.

FIG. 6A shows an image of BTB eye patterns of device B, measured without reflection, according to the present invention.

FIG. 6B shows an image of BTB eye patterns of device B, measured under an optical feedback (−12 dB), according to the present invention.

FIG. 6C shows an image of BTB eye patterns of device B, measured under an optical feedback (−6 dB), according to the present invention.

### DESCRIPTION OF THE PREFERRED EMBODIMENTS

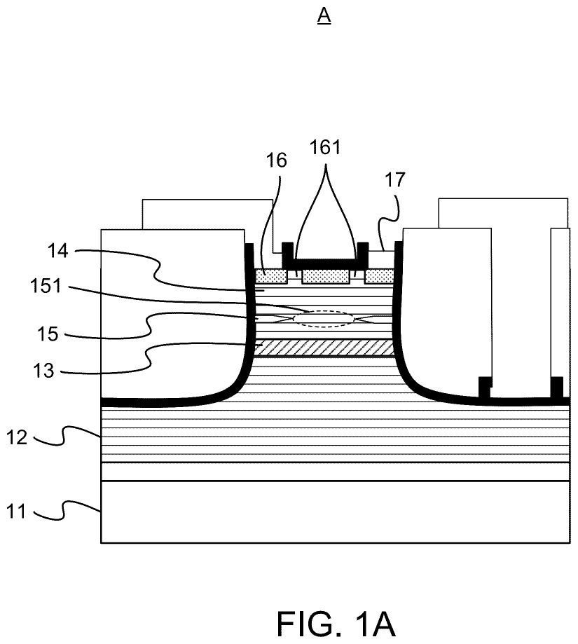

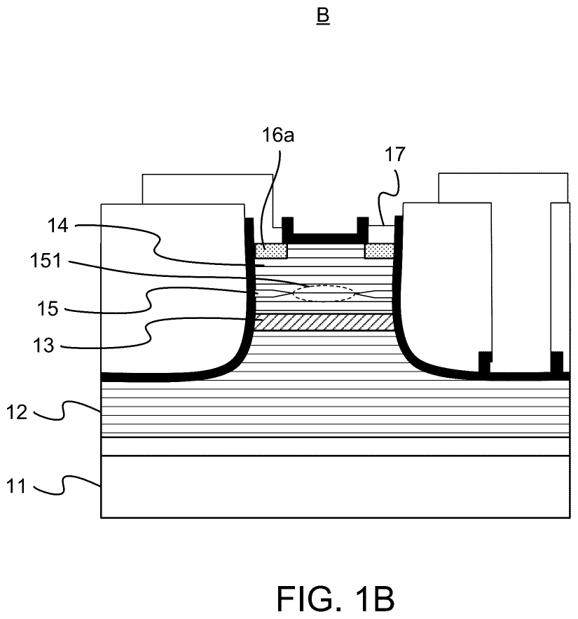

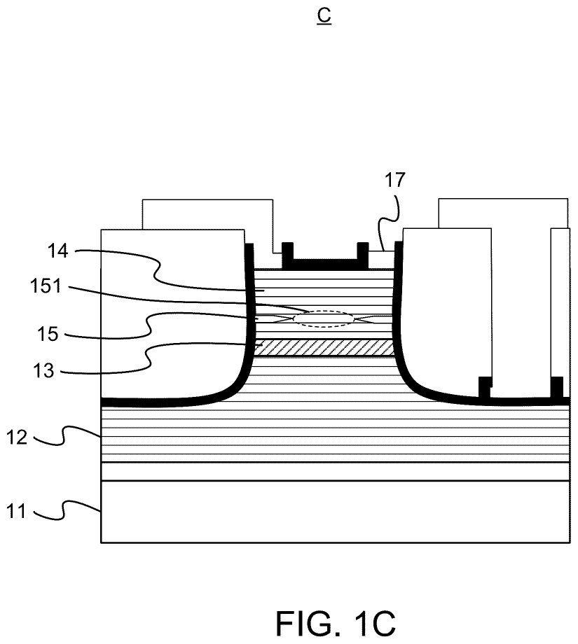

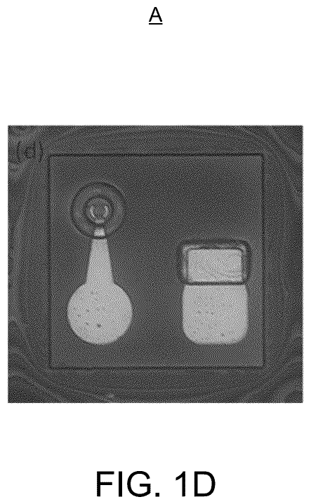

Please refer to FIG. 1A through FIG. 6C, which are a cross-sectional view of device A having a ring-shaped Zn-diffusion defined light-emission aperture according to the present invention, a cross-sectional view of device B exemplarily having a conventional Zn-diffusion structure, a cross-sectional view of reference device C exemplarily having not undergone any Zn-diffusion process, a top view of a VCSEL device having a ring-shaped Zn-diffusion defined light-emission aperture according to the present invention, a graph showing the L-I curve of device A measured according to present invention, a graph showing the L-I curve of device B, a graph showing the L-I curve of device C, a bias voltage spectral diagram of device A according to the present invention, a bias voltage spectral diagram of device B according to the present invention, a bias voltage spectral diagram of device C according to the present invention, a graph illustrative of measured bias-dependent E-O frequency responses of device A according to the present invention, a graph illustrative of measured bias-dependent E-O frequency responses of device B according to the present invention, a graph illustrative of measured bias-dependent E-O frequency responses of device C according to the present invention, an image of BTB eye patterns of device A, measured without reflection, according to the present invention, an image of BTB eye patterns of device A, measured under an optical feedback (−12 dB), according to the present invention, an image of BTB eye patterns of device A, measured under an optical feedback (−6 dB), according to the present invention, an image of BTB eye patterns of device B, measured without reflection, according to the present invention, an image of BTB eye patterns of device B, measured under an optical feedback (−12 dB), according to the present invention, an image of BTB eye patterns of device B, measured under an optical feedback (−6 dB), according to the present invention, respectively. As shown in the diagrams, the present invention is a VCSEL device having a ring-shaped Zn-diffusion defined light-emission aperture and configured to optimize the dimensions of a cavity structure and the ring-shaped light-emission aperture of the Zn-diffusion structure so as to fabricate a single-mode or multi-mode VCSEL device with excellent static and dynamic performance

In a preferred, specific embodiment of the present invention, the aforesaid novel structure achieves a record-high single-mode output power of 16 mW and a 3-dB electrical-to-optical (E-O) bandwidth of 18 GHz. Furthermore, a wide E-O bandwidth (27 GHz), high SM power (6.7 mW), low-RIN (−137 dB/Hz), and invariant 56 Gbps eye patterns are achieved under a strong optical feedback (−6 dB) through changing aperture dimensions to achieve high-speed operations.

Referring to FIGS. 1A˜1C, there are shown conceptual cross-sectional views of device A, device B, and device C respectively. Device A is the VCSEL device having a ring-shaped Zn-diffusion defined light-emission aperture according to the present invention, whereas devices B, C are conventional devices. Device A and device B respectively adopt oxidation-induced delamination and Zn-diffusion technology to reduce differential resistance and parasitic capacitance. Device C is a reference device that has not undergone any Zn-diffusion process. FIG. 1D is a top view of a VCSEL device of the present invention. The greatest bottleneck affecting the static and dynamic performance of a SM VCSEL is the spatial hole burning (SHB) effect. Preferably, the dimensions of an optical mode field in the VCSEL cavity are greater than the dimensions of the current-confined (oxide) region in order to minimize the SHB effect. However, in a conventional Zn-diffusion VCSEL device, the dimensions of the optical mode field defined by Zn-diffusion must be less than the dimensions of the current-confined region in order to support a higher SM output power (of around 10 mW). However, SHB-induced low-frequency roll-off leads to poor performance of strong signal transmission.

Referring to FIGS. 1A and 1B, a disk-shaped aperture of a conventional Zn-diffusion structure 16a is replaced with a ring-shaped light-emission aperture in device A. The ring-shaped Zn-diffusion structure 16 can effectively enlarge optical cavity size and sustain SM operations. In device A, the optical near-field is confined to the ring-shaped light-emission aperture, and a light-emission ring 161 defined by the ring-shaped light-emission aperture is near the edge of a p-contact 17 and a current-confined region 151. This layout effectively shortens a hole drift distance from the p-contact 17 to the ring-shaped light-emission aperture and minimizes the spatial hole burning effect of the conventional SM VCSEL. The geometric dimensions of the ring-shaped light-emission aperture of the present invention are optimized for quasi-single-mode (quasi-SM) operations within the entire range of bias current.

As shown in FIG. 1A, an epitaxial structure of the VCSEL device 100 is grown on an N⁺-type GaAs substrate 11 in a molecular beam epitaxy (MBE) chamber. The epitaxial structure comprises a bottom DBR 12, a light-emission region (active region) 13 stacked on the bottom DBR 12, and a top DBR 14 stacked on the light-emission region 13. A wet oxidation, etching-defined undercut structure or ion-implantation region is defined on the light-emission region 13. The central portion of the ion-implantation region 15 or the undercut structure is the current-confined region 151. A Zn-diffusion structure 16 is disposed in the top DBR 14 and located at the ring-shaped light-emission aperture in the central region on the top surface of the top DBR 14 such that light emission is focused into the light-emission ring 161 defined by the Zn-diffusion structure 16. The diameter of the current-confined region 151 closely approximates the outer diameter of the light-emission ring 161 defined by the Zn-diffusion structure 16 and is less than 10 μm. The light-emission region 13 consists of four layers of compressive strain In_{0.07}Ga_{0.93}As/Al_{0.3}Ga_{0.7}As MQW, wherein its photoluminescence (PL) peak wavelength is around 838 nm and is disposed between 39-pairs of n-type and 24-pairs of p-type Al_{0.93}Ga_{0.07}As/Al_{0.15}Ga_{0.85}As DBRs 14, 12, wherein an oxidation layer (not shown) of Al_{0.98} Ga_{0.02}As is disposed above the MQW. Compared with device B (i.e. a conventional Zn-diffusion VCSEL device), both the structure and geometric dimensions of the ring-shaped Zn-diffusion defined light-emission aperture of device A of the present invention are further optimized to minimize the SHB effect of high power and SM operations.

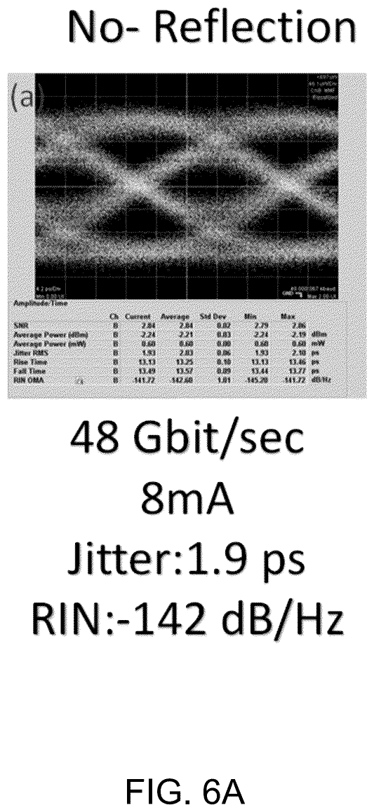

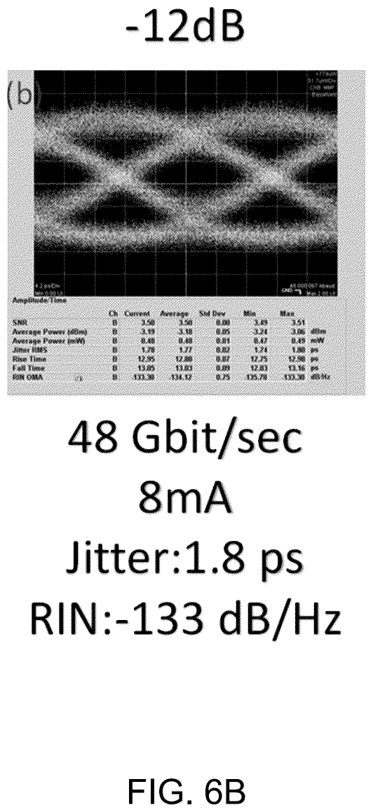

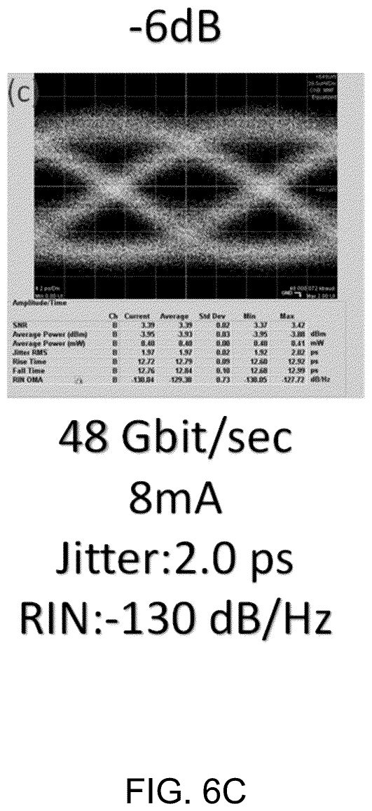

The embodiment below exemplarily illustrates the technical features of the present invention but is not restrictive of the claims of the present invention. As shown in FIG. 1A˜FIG. 6C, device A and device B have a Zn-diffusion diameter (W_{z}) of 5 μm, whereas the current-confined regions of device A, device B and device C have a diameter (Wₒ) of 5 μm, with Zn-diffusion depth (d) of 1 μm.

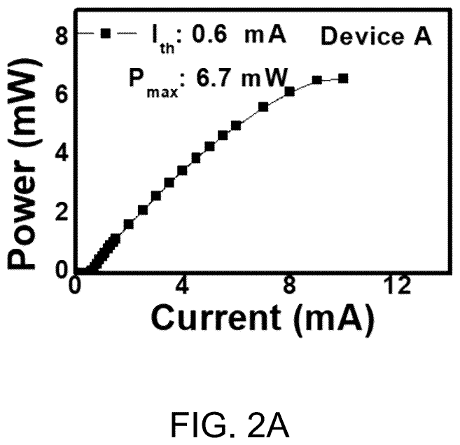

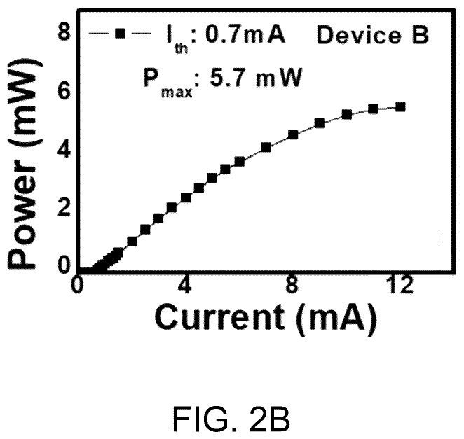

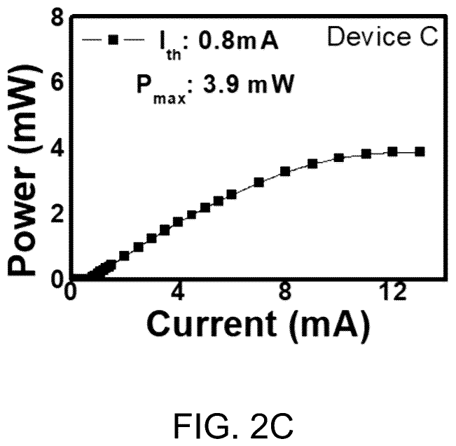

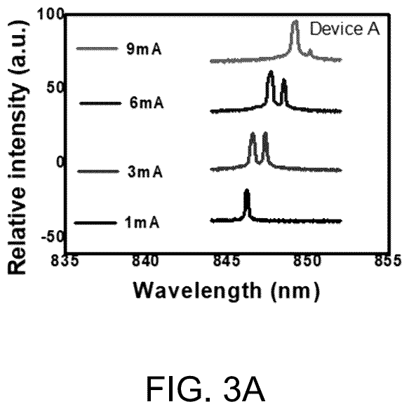

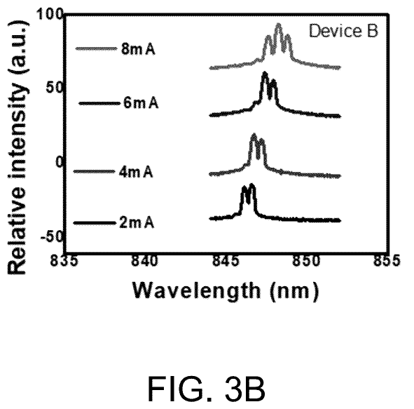

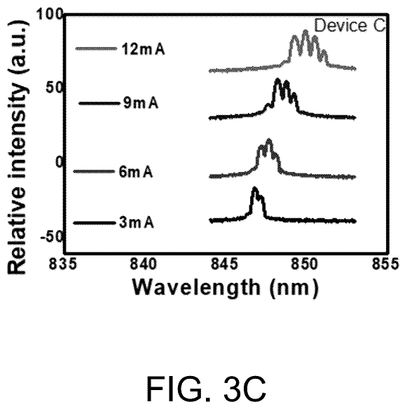

FIGS. 2A˜2C are graphs showing curves illustrative of the characteristics of input current versus light output, as measured with device A capable of novel Zn-diffusion, device B capable of conventional Zn-diffusion, and reference device C having no Zn-diffusion aperture respectively, where Wₒ/W_{z}/d=5/5/1 μm. FIG. 3A˜3C show bias voltage spectral diagrams of device A, device B and device C according to the present invention respectively (Wₒ/W_{z}/d=5/5/1 μm). Compared with device B, device A has a Zn-diffusion structure that has been modified to minimize the SHB effect to the largest extent possible. Therefore, the bias voltage spectrum of device A is significantly cleaner than those of device B and reference device C.

As shown in FIG. 2 and FIG. 3, among the three devices, device A has the best static performance in terms of the highest slope efficiency (SE) and quasi-SM output power. A further increase in the bias currents of device B and device C, i.e., >3 mA, causes MM output. Device A maintains SM performance at the maximum bias current of 9 mA, with a side-mode suppression ratio (SMSR) of 20 dB, to achieve maximum output power (˜6.7 mW). Owing to their Zn-diffusion apertures, both device A and device B exhibit a better slope efficiency (SE) than that of the reference device C fabricated without Zn-diffusion. Such an enhancement of the SE has been reported for the conventional VCSEL devices with a Zn-diffusion structure can be attributed to the fact that the Zn-diffusion profile provides a low-resistivity current flow path just above the current-confined region. This should increase the injection efficiency (ηᵢ) of the external injected carriers into the light emission active region and result in the improved SE. Moreover, in contrast to that of device B, which usually have strongest output light intensity at the center of the current-confined region and Zn-diffusion aperture, the output light of device A is concentrated in the light-emission ring 161 defined by the Zn-diffusion structure 16, with the light-emission ring 161 being near the edge of the current-confined region 151, as shown FIG. 1A. This layout effectively shortens the hole drift distance from the p-contact 17 to the ring-shaped light-emission aperture and further enhances the SE and ηᵢ of device A. Besides, in the conventional Zn-diffused VCSEL in device B, the higher SE rarely leads to a higher maximum output power (Pₘₐₓ), because the high SM output is usually accompanied by a pronounced SHB effect. This becomes a major bottleneck for higher Pₘₐₓ and speed in high-power SM VCSELs. Obviously, device A, with the ring-shaped Zn-diffusion defined light-emission aperture, exhibits better static performances in terms of larger SM power, higher SE, and larger Pₘₐₓ than those of devices B and C. Such a result indicates that the novel VCSEL device with the Zn-diffusion structure can effectively overcome the SHB bottleneck which happens in the high-power SM VCSEL.

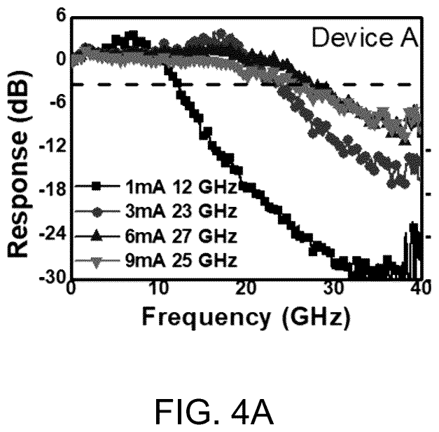

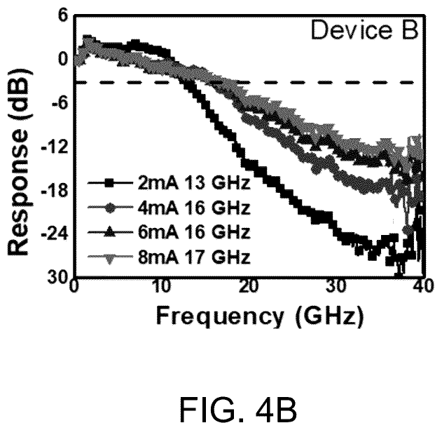

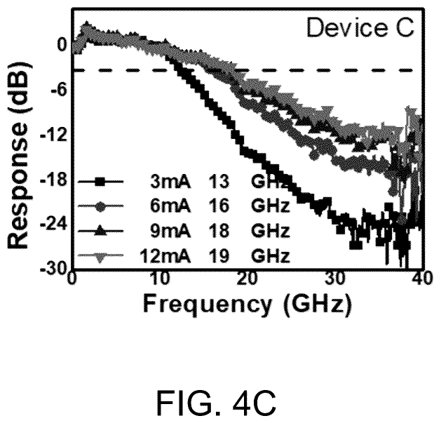

The high-speed E-O performance of the fabricate VCSEL device is measured with a lightwave component analyzer (LCA) The LCA consists of a network analyzer and a calibrated photoreceiver module and covers the wavelength 850˜1310 nm of an optical window. At the wavelength of 850 nm, the E-O −3 dB bandwidth measured with the module is around 27 GHz. FIGS. 4A˜4C show the bias-dependent E-O frequency responses (Wₒ/W_{z}/d=5/5/1 μm) measured with device A, device B, and device C respectively.

At a bias current of 6 mA, device A achieves a 3 dB E-O bandwidth of 27 GHz indicative of a speed much higher than that (16 GHz) achieved by device B and device C at the same bias current of 6 mA. When the bias current is over 3 mA, all the measured E-O frequency responses become flat and heavily damp, which implies a low RIN performance during high-speed operation. This result contrasts with the dynamic behavior reported for most SM and high-power VCSELs, whose quasi-SM performance is typically accompanied by a pronounced low-frequency roll-off and significant resonance in E-O frequency responses, resulting in serious degradation of the strong signal transmission performance. Such low-frequency roll-off is caused by the excessive hole transport time in the transverse direction from the p-contact to the center of the current-confined region, where the peak intensity of output light lies. It can be represented by an extra low-pass filter in the E-O transfer function of semiconductor laser. As shown in FIGS. 1A˜1C and FIGS. 2A˜2C, device A surpasses device B and device C in terms of speed performance (because of its novel ring-shaped Zn-diffusion defined light-emission aperture) to fundamentally shorten hole transport time, suppress the spatial hole burning effect, pull up the carrier transport time limited bandwidth, and bring about an enhancement of net E-O bandwidth.

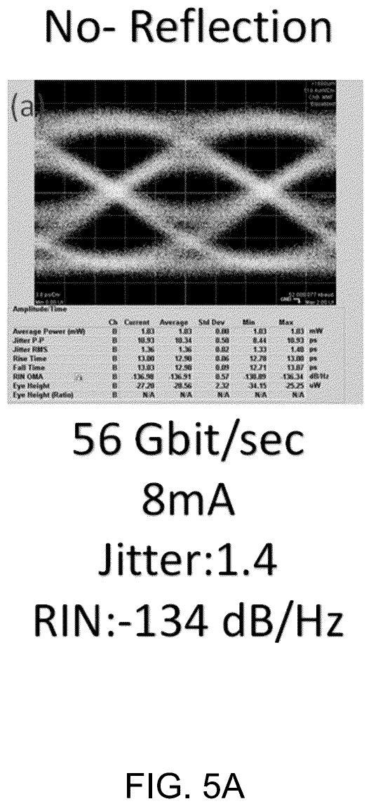

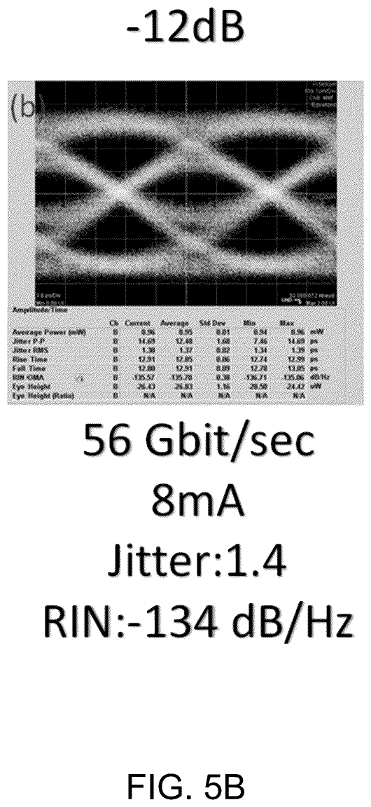

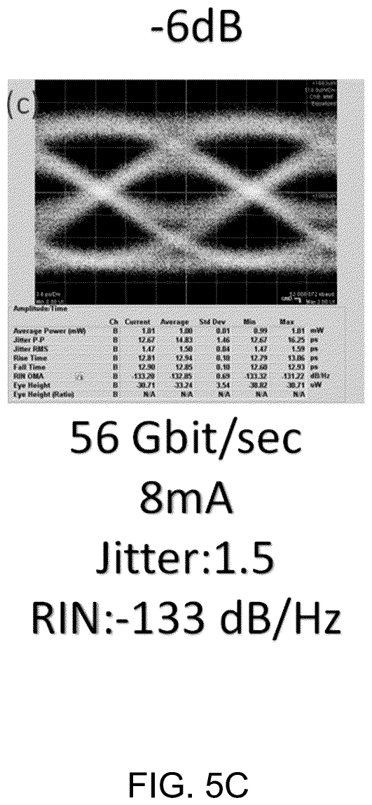

FIGS. 5A˜5C and FIGS. 6A˜6C show BTB eye patterns (Wₒ/W_{z}/d=5/5/1 μm) measured with device A and device B under different optical feedback stress (without reflection, −12 dB, and −6 dB) respectively. The findings of the diagrams are as follows: device A can still maintain invariant 56 Gbit/sec eye patterns under a strong optical feedback (−6 dB) and exhibit a RIN OMA (−133 vs. −130 dB/Hz) lower than that of device B at a lower data transmission rate (48 vs. 56 Gbit/sec). The slightly better RIN performance of device A compared to that of device B may be attributed to their different near-field distributions. Although device A has a ring-shaped light-emission aperture, it has a Gaussian-like far-field pattern with peak intensity at the center. This implies that the distribution of reflected beam differs from its near-field pattern, where most of output light concentrates at the peripheral of the ring-shaped light-emission aperture. Such discrepancy between the near-field and the far-field of the reflected beam of device A can explain the improved RIN performance of device A under optical feedback stress.

The present invention provides a novel VCSEL device having a ring-shaped Zn-diffusion defined light-emission aperture and replaces the conventional aperture of a Zn-diffusion structure with a ring-shaped light-emission aperture such that the light emission is focused into a light-emission ring defined by the ring-shaped Zn-diffusion defined light-emission aperture. The light-emission ring is near the edge of a current-confined region to effectively shorten the hole drift distance from a p-contact to the light-emission aperture, further enhance injection efficiency and slope efficiency, minimize the spatial hole burning effect, and enhance the immunity against optical feedback to achieve a record-high SM output power of 16 mW and a 3-dB E-O bandwidth of 18 GHz. The ring-shaped Zn-diffusion defined light-emission aperture is effective in achieving high-speed operations and achieving the most advanced performance without using any equalizers, for example, under a strong optical feedback (−6 dB) to achieve wide E-O bandwidth (27 GHz), high SM power (6.7 mW), low-RIN (−137 dB/Hz), and invariant 56 Gbps eye patterns.

In conclusion, the present invention is a VCSEL device having a ring-shaped Zn-diffusion defined light-emission aperture to effectively overcome the drawbacks of the prior art and replace an aperture of a Zn-diffusion structure with a ring-shaped light-emission aperture to focus light emission into a light-emission ring defined by the ring-shaped light-emission aperture and thereby attain excellent VCSEL device performance, for example, under a strong optical feedback (−6 dB) to achieve wide E-O bandwidth (27 GHz), high SM power (6.7 mW), low-RIN (−137 dB/Hz), and invariant 56 Gbps eye patterns so as to achieve high-speed operations. Therefore, the present invention is not only novel and practical but also meets user needs, thereby fulfilling the requirements for patentability.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A VCSEL device having a ring-shaped Zn-diffusion defined light-emission aperture, comprising:
a top DBR disposed in an epitaxial structure of the VCSEL device and having therein a Zn-diffusion structure, with the Zn-diffusion structure located at a ring-shaped light-emission aperture in a central region on a top surface of the top DBR to focus light emission into a light-emission ring defined by the Zn-diffusion structure, allowing the light-emission ring to be near an edge of a current-confined region disposed in the epitaxial structure, so as to effectively shorten a hole drift distance from a p-contact to the light-emission aperture, further enhance injection efficiency and slope efficiency, and minimize a spatial hole burning effect.

2. The VCSEL device having a ring-shaped Zn-diffusion defined light-emission aperture according to claim 1, wherein the epitaxial structure is stacked on a substrate selected from one of P-type, N-type, and semi-insulating semiconductor.

3. The VCSEL device having a ring-shaped Zn-diffusion defined light-emission aperture according to claim 1, wherein the epitaxial structure further comprises a bottom DBR and a light-emission region (active region) stacked on the bottom DBR, with the top DBR being stacked on the light-emission region, allowing one of a wet oxidation, etching-defined undercut structure, and ion-implantation region to be defined on the light-emission region, with the current-confined region being a central portion of one of the undercut structure and the ion-implantation region.

4. The VCSEL device having a ring-shaped Zn-diffusion defined light-emission aperture according to claim 1, wherein a diameter of the current-confined region closely approximates an outer diameter of the light-emission ring defined by the Zn-diffusion structure and is less than 10 μm.

5. The VCSEL device having a ring-shaped Zn-diffusion defined light-emission aperture according to claim 1, wherein the VCSEL device is fabricated using one of metal-organic chemical vapor deposition (MOCVD) and molecular beam epitaxy (MBE).

6. The VCSEL device having a ring-shaped Zn-diffusion defined light-emission aperture according to claim 1, wherein the VCSEL device is one of a single-mode (SM) VCSEL and a multi-mode (MM) VCSEL.

7. The VCSEL device having a ring-shaped Zn-diffusion defined light-emission aperture according to claim 1, wherein the VCSEL device is an 850 nm SM VCSEL effective in enhancing output power and speed of the VCSEL in a single-mode fiber (SMF).

8. The VCSEL device having a ring-shaped Zn-diffusion defined light-emission aperture according to claim 1, wherein excellent VCSEL performance can be obtained by varying the aperture size for high-speed operations, such as wide E-O bandwidth (27 GHz), high SM power (6.7 mW), low-RIN (−137 dB/Hz), and invariant 56 Gbps eye patterns under a strong optical feedback (−6 dB).

9. The VCSEL device having a ring-shaped Zn-diffusion defined light-emission aperture according to claim 1, wherein immunity against optical feedback is enhanced to achieve an SM output power of 16 mW and a 3-dB E-O bandwidth of 18 GHz.
